(19) United States
(12) Patent Application Publication
(10) Pub. No.: US 2017/0133431 A1
(43) Pub. Date: May 11, 2017

(54) Direct Growth Of Optoelectronic Devices On CMOS Technology

(71) Applicant: THE REGENTS OF THE UNIVERSITY OF MICHIGAN, Ann Arbor, MI (US)

(72) Inventors: Joanna MIRECKI-MILLUNCHICK, Ann Arbor, MI (US); Jamie PHILLIPS, Ann Arbor, MI (US); Alan S. TERAN, Brookline, MA (US); Matthew T. DEJARLD, Ann Arbor, MI (US)

(21) Appl. No.: 15/349,059

(22) Filed: Nov. 11, 2016

Related U.S. Application Data
(60) Provisional application No. 62/253,912, filed on Nov. 11, 2015.

(51) Int. Cl. H01L 27/15; H01L 33/04; H01L 33/00; H01L 33/30; H01L 33/40; H01L 27/092; H01L 33/08

(52) U.S. Cl. CPC H01L 27/15; H01L 27/092; H01L 33/04; H01L 33/08; H01L 33/30; H01L 33/305; H01L 33/40; H01L 33/0066; H01L 2933/0016

(57) ABSTRACT

With an increasing demand for miniature low power sensors, there is a need to integrate optoelectronic devices with CMOS technology. Deposition of GaAs nanowires on polycrystalline conductive films allows for direct integration of optoelectronic devices on dissimilar materials. Nanowire growth is demonstrated on oxide and metallic films. Introducing dopant elements modifies the surface energy improving nanowire morphology and lowing for core-shell growth. Electrical measurements confirm that the metal-semiconductor junction is Ohmic and thus the feasibility of integrating nanowire-based devices directly on CMOS devices.

### CROSS-REFERENCE TO RELATED APPLICATIONS

This application claims the benefit of U.S. Provisional Application No. 62/253,912 filed on Nov. 11, 2015. The entire disclosure of the above application is incorporated herein by reference.

### GOVERNMENT CLAUSE

This invention was made with government support under CA190498 awarded by the National Institutes of Health. The Government has certain rights in the invention.

### FIELD

The present disclosure relates to techniques for fabricating an optoelectronic device.

### BACKGROUND

Wireless sensor networks are the backbone of the evolving system of interconnected commercialized devices known as the Internet of Things. These networks are comprised of low power sensor nodes utilized in smart appliances, environmental monitors, and implantable biomedical devices. Millimeter scale sensors have already demonstrated energy-autonomous operation using photovoltaic cells in conjunction with both solar and indoor lighting. Incorporation of optoelectronic devices into wireless sensor nodes is currently achieved externally by wire bonding separate components into a stacked unit. Integrating silicon CMOS and III-V optoelectronic devices as a single component would eliminate the need for wire bonding and decrease the thickness. Material incompatibility, especially between the Si-based logic circuits and the GaAs-based optoelectronics, limits this approach due to defects formed between dissimilar materials.

Therefore, it is desirable to develop techniques for fabricating optoelectronic devices which can be integrated with CMOS technology. This section provides background information related to the present disclosure which is not necessarily prior art.

### SUMMARY

This section provides a general summary of the disclosure, and is not a comprehensive disclosure of its full scope or all of its features.

A method is presented for fabricating an optoelectronic device. The method includes: forming a bottom contact layer on a substrate; growing a plurality of nanowires on the bottom contact layer at a temperature less than or equal to 450 degrees Celsius, where the nanowires are comprised of a group III-V semiconductor material; depositing an insulating material onto the nanowires to form an active layer; and forming a top layer on top of the active layer, where the top layer and the bottom contact layer are comprised of a conductive material. A catalyst may be deposited onto the bottom contact layer prior to the step of growing the plurality of nanowires.

In one embodiment, the nanowires are comprised of gallium arsenide doped with beryllium. In particular, the plurality of nanowires are grown by first depositing gallium arsenide doped with beryllium onto the bottom contact layer and then depositing gallium arsenide dopes with silicon onto the deposited gallium arsenide doped with beryllium.

In another aspect, an integrated circuit package is formed with a complementary metal-oxide-semiconductor (CMOS) device and an optoelectric device. The optoelectric device includes an active region comprised of nanowires and the active region is sandwiched between a top contact layer and a bottom contact layer, wherein the nanowires are grown from a group III-V semiconductor materials at or below 450 degrees Celsius.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a flowchart depicting an example method for fabricating an optoelectronic device in accordance with this disclosure;

FIG. 2A shows a top down scanning electron microscope image of GaAs nanowires grown on indium tin oxide for 30 minutes;

FIG. 2B shows a cross sectional scanning electron microscope image of GaAs nanowires grown on indium tin oxide for 30 minutes

FIG. 2C shows a high magnification SEM image of the GaAs-ITO interface, with the interface between the ITO and GaAs indicated;

FIGS. 3A-3C are graphs illustrating the nanowire forest height, nanowire growth angle, and continuous layer thickness, respectively, of GaAs nanowires grown on ITO as a function of growth time;

FIG. 4A shows a cross-sectional SEM image of GaAs nanowires grown on ITO for 15 minutes with no doping;

FIG. 4B shows a cross-sectional SEM image of GaAs nanowires grown on ITO for 15 minutes with Si doping;

FIG. 4C shows a cross-sectional SEM image of GaAs nanowires grown on ITO for 15 minutes with Be doping;

FIGS. 5A and 5B show transmission electron microscope images and diffraction patterns of undoped GaAs nanowires grown on ITO;

FIGS. 5C and 5D show transmission electron microscope images and diffraction patterns of SI doped GaAs nanowires grown on ITO;

FIGS. 5E and 5F show transmission electron microscope images and diffraction patterns of Be doped GaAs nanowires grown on ITO;

FIG. 6A is a graph showing photoluminescence data of nanowires grown on ITO with no doping;

FIG. 6B is a graph showing photoluminescence data of nanowires grown on ITO with Si doping;

FIG. 6C is a graph showing photoluminescence data of nanowires grown on ITO with Be doping;

FIG. 7A shows a plan-view SEM image of GaAs nanowires grown on Pt films at low Ga fluxes (6×10⁻⁷);

FIG. 7B shows a plan-view SEM image of GaAs nanowires grown on Pt films at high Ga fluxes (9×10⁻⁷);

FIG. 7C shows a plan-view SEM image of GaAs nanowires grown on Pt films along with the addition of Si dopants at the higher deposition rate;

FIG. 7D shows a plan-view SEM image of GaAs nanowires grown on Pt films along with the addition of Be dopants at the higher deposition rate;

FIG. 8A shows a cross-sectional SEM image of Be-doped GaAs nanowires grown for 30 min on a Ti film;

FIG. 8B is a graph showing I-V characteristics of Be-doped nanowires on Ti;

FIG. 8C is a graph showing temperature dependent photoluminescence of Be-doped nanowires on Ti;

FIG. 8D is a graph showing the position of peaks 1 and 2 plotted against temperature;

FIG. 8E is a graph showing the intensity of peaks 1 and 3 plotted against temperature; and

FIG. 9 is a diagram of an example optoelectric device integrated with a CMOS device.

Corresponding reference numerals indicate corresponding parts throughout the several views of the drawings.

### DETAILED DESCRIPTION

Example embodiments will now be described more fully with reference to the accompanying drawings.

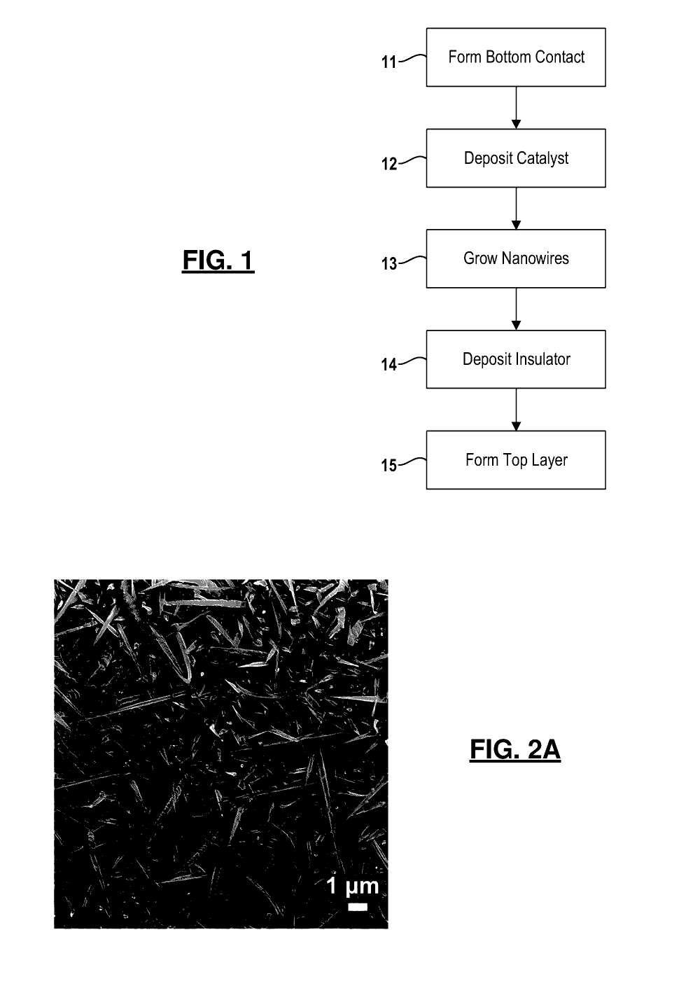

FIG. 1 depicts an example method for fabricating an optoelectric device in accordance with this disclosure. As a first step, a bottom contact layer is formed at 11 on a planar surface. In one embodiment, the bottom contact layer is formed on a top surface of a CMOS circuit. In other embodiments, the bottom contact layer may be formed on a substrate, such that the optoelectric device is lateral or otherwise proximate to a CMOS circuit prior to integrated circuit packaging.

Nanowires are then grown at 13 on the bottom contact layer at a temperature less or equal to 450 degrees Celsius. Nanowires are readily understood to be nanostructures with a diameter on the order of a nanometer and the ration of the length to width being greater than one thousand. Nanowires are nanowires are comprised of a group III-V semiconductor materials. For example, gallium arsenide is deposited onto the bottom contact layer, for example using molecular beam epitaxy. Other suitable semiconductor materials and/or compounds include but are not limited to indium arsenide, aluminum arsenide, gallium antimonide, indium antimonide, indium phosphide, gallium phosphide, and their corresponding ternary alloys. Other techniques for depositing the material are also contemplated by this disclosure.

To enhance growth, the semiconductor materials are preferably doped. In an example embodiment, gallium arsenide doped with beryllium is deposited onto the bottom contact layer from which nanowires are grown. Gallium arsenide doped with silicon is then deposited over top of the nanowires grown from gallium arsenide doped with beryllium. The gallium arsenide doped with silicon adheres to the existing nanowires and thereby increase the size of the nanowires. The gallium arsenide doped with silicon is electrically isolated from the bottom contact layer. A PN junction is formed in the nanowires at the interface between the gallium arsenide doped with beryllium and the gallium arsenide doped with silicon. Example dopants include but are not limited to antimony, bismuth, magnesium, sulfur, tellurium, and zinc.

Prior to depositing the semiconductors materials, a catalyst is optionally deposited onto the bottom contact layer as indicated at 12 and prior to the step of growing nanowires. The catalyst both prevents oxidation and acts as a catalyst for nanowire growth. Example catalysts include but are not limited to gold, nickel, silver and tin.

Following nanowire growth, the nanowires are backfilled at 14 with an insulating material to form an active region of the optoelectric device. In one example, the insulating material is a polymer although other types of materials are contemplated as well.

Lastly, a top contact layer is formed over the active region as indicated at 15. The top and bottom contact layers are preferably made of a conductive material and thereby provide terminals for the active region. Conductive materials may include but are not limited to gold, silver, copper, etc. Depending on the function of the device, the top contact layer may be comprised of a transparent material which permits light to be incident upon the surface of the active region of the device.

The maximum growth temperature possible for integrating nanowires with CMOS was found by heating sensors containing wire-bonded stacks of Si devices in a molecular beam epitaxy chamber, after which they were tested for functionality and electrical conductivity. These samples were heated to 300° C., 400° C., and 500° C. and annealed for 30 min and removed. Devices annealed to 500° C. exhibited open circuit responses; whereas, samples heated to 400° C. and 300° C. remained functional, consistent with other CMOS temperature studies. Thus, all subsequent nanowire growths were conducted at substrate temperatures of 400° C. While reference is made throughout this disclosure to 400° C., other temperatures below 450° C. also fall within the scope of this disclosure.

For demonstration purposes, three polycrystalline films were examined as substrate candidates, indium tin oxide, platinum, and titanium. For the samples with ITO films, oxide-free p-doped silicon substrates were coated with 100 nm of ITO at room temperature at rate of 1.8 A s−¹ with 40 sccm Ar and 1 sccm O₂ at 139 W of DC power. For samples with Pt films, Pt/Ti0/Si/Si0₂ substrates were purchased from Radiant Technologies. For samples with Ti films, 4 nm of titanium was e-beam deposited on oxide-free Si wafers using an Eneijet system.

Each substrate was coated with a thin film of Au to act as the catalyst necessary for nanowire growth although other types of catalysts are envisioned. For both ITO and Pt films, 5 nm of gold (Au) was sputter coated at room temperature under 5 mTorr vacuum for 16 s with the Ar plasma at 18 V. For the Ti film, 5 nm of Au was deposited using e-beam deposition immediately after Ti deposition. This both prevents Ti oxidation and acts as the catalyst for nanowire growth.

The GaAs nanowires are grown using molecular beam epitaxy chamber using the well known vapor-liquid-solid (VLS) mechanism. GaAs growth without an Au catalyst resulted in the growth of a rough film and no nanowires. Samples were heated to 400° C., after which they were exposed to an As₄ flux. To initiate growth, Ga was introduced at a rate either 0.8 or 1.3 monolayers s⁻¹ (MLs⁻¹). The ratio of As₄/Ga beam equivalent pressures was 10 in all growths. Growth times varied between 5≦t≦60 min. RHEED measurements show a quick transition from the ringed diffraction pattern of the polycrystalline substrate, to a complete loss of signal associated with scattering from the random array of nanostructures. In an example embodiment, Si and Be elemental sources were used as n and p type dopants as indicated, using fluxes that result in Si and Be doping concentrations of 4×10¹⁹ cm⁻³ in planar GaAs films.

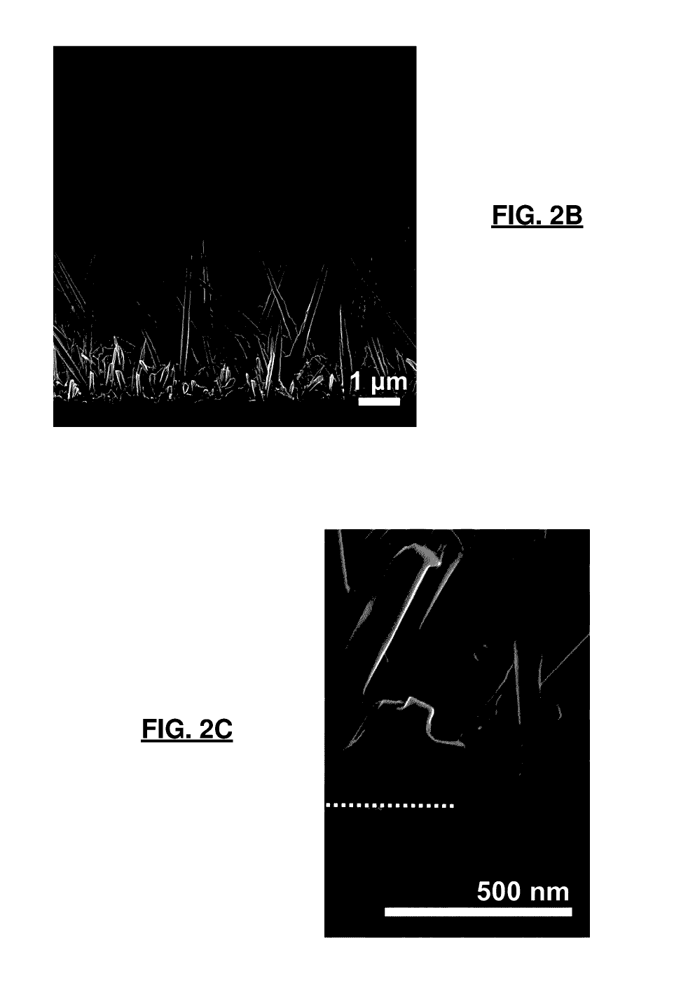

FIGS. 2A-2C shows scanning electron microscope (SEM) images of nanowires grown on indium tin oxide (ITO), a conductive oxide widely used as a top contact in photovoltaic applications due to its transparency. These micrographs show that the nanowires grow in many different directions, forming a dense forest. The nanowires are heavily tapered and often end in a sharp point. This type of tapered morphology is also seen in GaAs nanowires grown on crystalline substrates. FIG. 2B is a cross sectional image of the sample in FIG. 2A. The majority of nanowires extends in a direction not parallel to the surface normal, and varies in length. A higher density of short and thin nanowires is present near the GaAs/ITO interface. FIG. 2C is a higher magnification image of the GaAs-ITO interface (indicated by the dotted line), and shows a layer of continuous GaAs at the base of the nanowires. Energy dispersive electron x-ray spectroscopy on the continuous film above the ITO layer in FIG. 2C confirms that it is GaAs. In all of the samples measured both nanowires and the continuous film are present.

The variation in the nanowire angle with respect to the substrate may have one of two causes: epitaxial or random nucleation. An epitaxial relationship between the polycrystalline ITO and GaAs is improbable given the 79% lattice mismatch between them. Rather, the nanowire growth is likely initiated by random nucleation events at the catalyst-film interface. Initially the angle of the nanowires is expected to be random with respect to the substrate normal and is responsible for the variation in nanowire heights in FIG. 2B. As the nanowires continue to increase in length, those growing at shallow angles will tend to terminate either by impinging on, or becoming shadowed by other nanowires. Collisions with growing nanowires can be seen in FIG. 2C. This explains why there are very thin and short nanowires near the substrate. The tapering observed in FIG. 2 is likely from a combination of sidewall growth and a shrinking catalyst, which are both well-documented phenomena in molecular beam epitaxy growth of undoped and Si-doped GaAs.

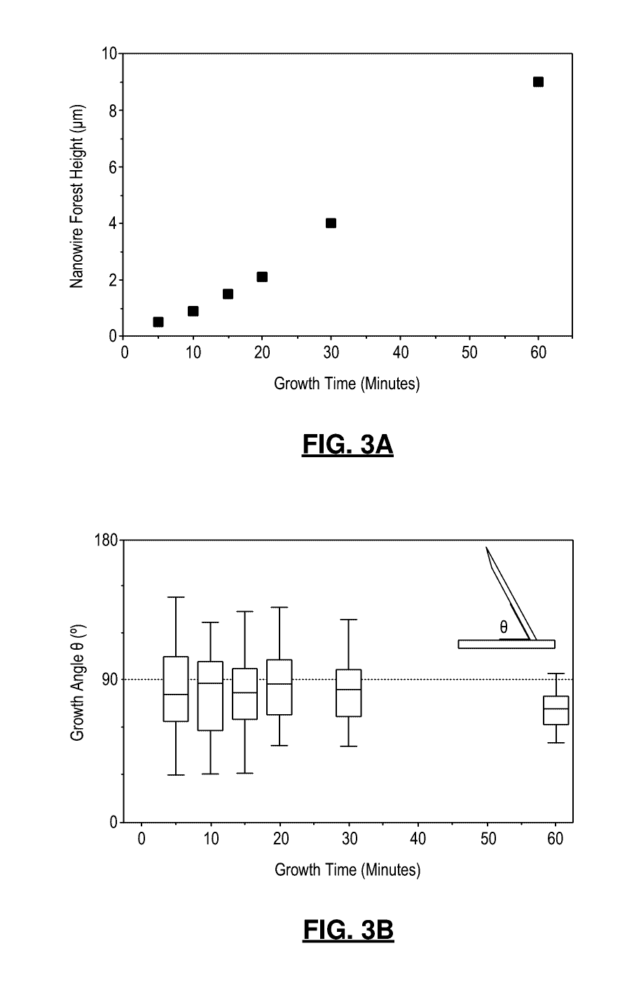

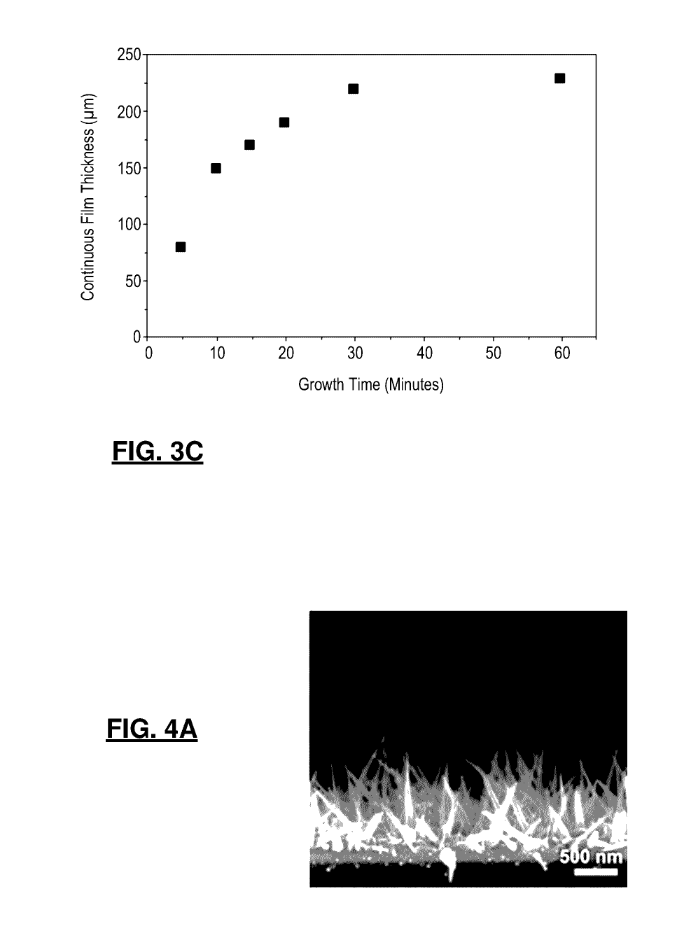

FIGS. 3A-3C plot the nanowire forest height, nanowire growth angle, and continuous layer thickness of GaAs nanowires grown on ITO as a function of growth time. The forest height, defined as the upper limit of the perpendicular distance between the nanowire tip and the substrate, has a strong positive linear correlation to the growth time (R²=0.992), as expected. FIG. 3B is a box and whisker plot showing the distribution of the angle between the nanowires and the underlying substrate. A minimum of thirty nanowires was measured on each sample. The range (denoted by the error bars) of the distribution decreases with deposition time, consistent with the fact that nanowires with shallow angles impinge on other nanowires or are shadowed by tilted nanowires. The interquartile range (denoted by the box) also decreases with deposition time, signifying a reduction in nanowire angle variation. After an hour of growth, the median nanowire angle converges towards −70°. This convergence is somewhat surprising, because if all growth directions were equally possible, the distribution should center around 90°. However, an angled direction presents a larger capture surface for the impinging flux allowing tilted nanowires close to the surface normal to grow faster. FIG. 3C shows the thickness of the continuous film as a function of growth time. The film thickness increases with growth time and saturates at a thickness of 230 nm. This behavior suggests that the continuous film is not a precursor to nanowire growth, but a competitive process. As the nanowires get longer, the impinging flux is captured by the nanowires as opposed to reaching the continuous layer.

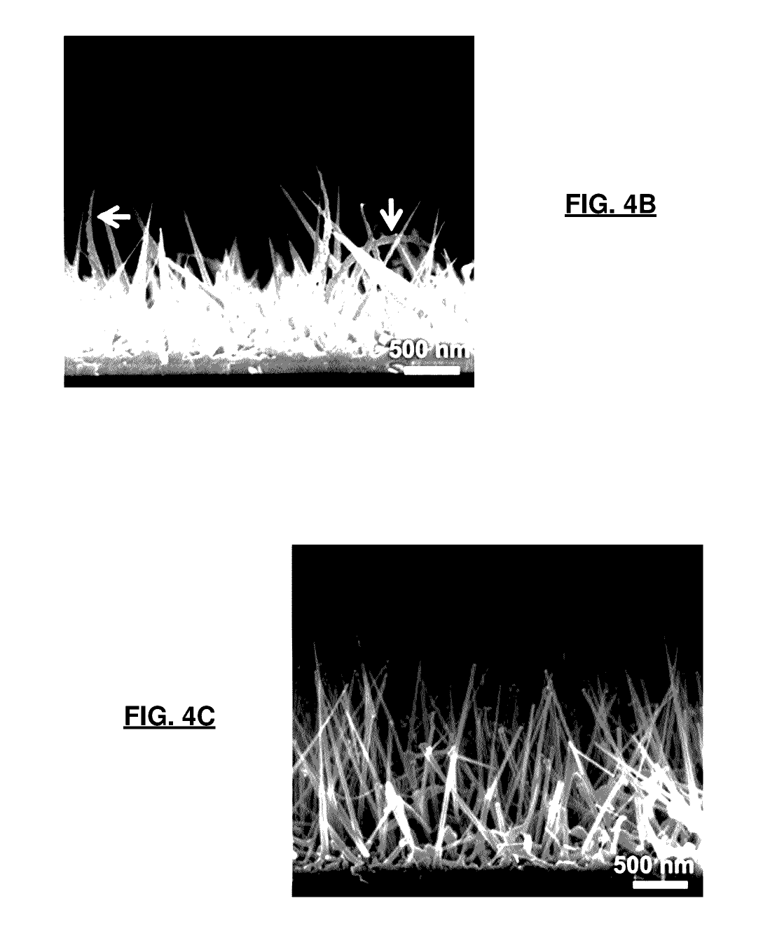

FIGS. 4A-4C show the effect of incorporating dopants into the growth of nanowires on ITO. FIG. 4A is an SEM image of undoped GaAs nanowires deposited for 15 min. The nanowire density is nominally 10⁸ cm⁻² and as before, the nanowires extend in random directions and are heavily tapered. The overall morphology of Si-doped nanowires (FIG. 4B) is similar to the undoped wires with a nanowire density of on the order of 10⁸ cm⁻², except that some nanowires are curved with rough sidewalls (indicated in FIG. 4B with arrows). Because they consistently curve towards the surface, it is likely that this curvature arises due to the fact that the side wall facing the impinging flux grows more quickly than the opposite sidewall. Furthermore, the side of the nanowire on the outside of curve tends to be very rough (arrows in FIG. 4B). It is known that Si doping decreases both the Si and Ga vacancy diffusion coefficient in bulk GaAs. In nanowires, dopant incorporation is dominated by diffusion on the sidewalls as opposed to dissolution within the catalyst. Thus, Si-doping would be expected to reduce diffusion on the sidewalls, promoting lateral growth of the nanowires.

Be-doping (FIG. 4C) leads to an increase in nanowire density (to 2.5±0.6×10⁸ cm⁻²), a reduction in nanowire diameter, and an increase in nanowire forest height (to 2.2±0.2 μm). These nanowires are less tapered, and tend to be aligned more closely to the surface normal. Thus, the Be dopant appears to have a surfactant effect on the nanowire sidewalls, improving the diffusion of Ga and As. This behavior has been observed for sulfur atoms during the growth of GaSb nanowires.

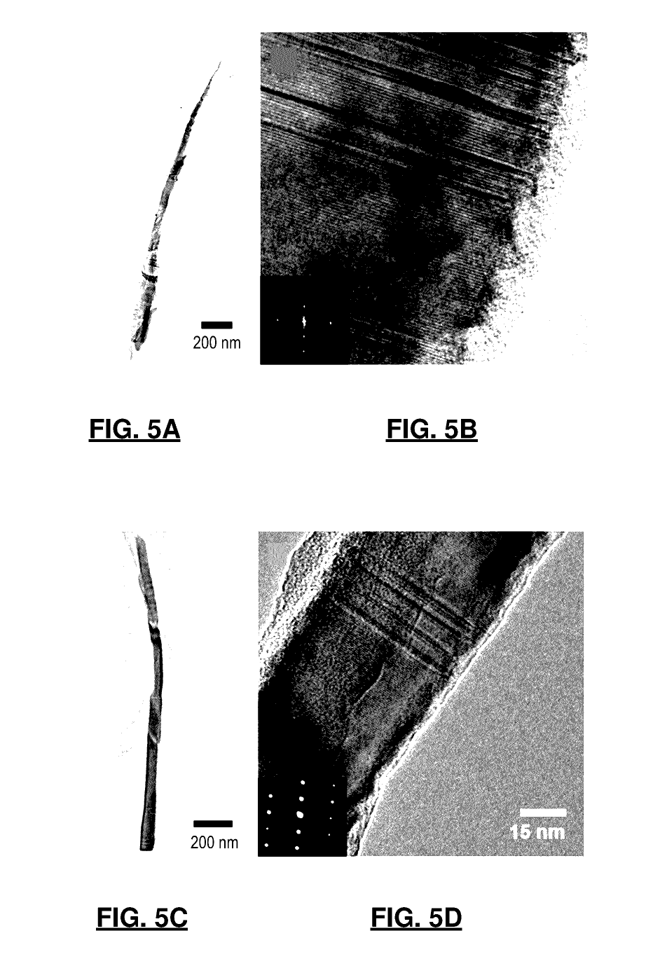

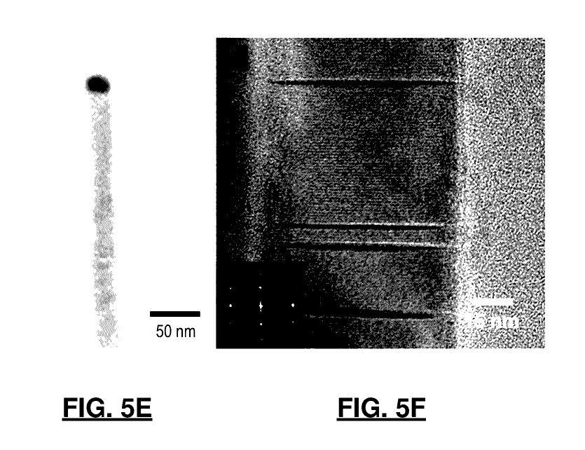

Transmission electron microscope (TEM) measurements also show that the microstructure of the nanowires varies with doping. The TEM samples were made by removing the nanowires from the substrate and dispersing them on a grid. FIG. 5A is a collection of TEM images used to form a single image of an undoped nanowire. The nanowire has very rough sidewalls, evidence of stacking faults, tapering, and ends in a sharp point. There is no evidence of the Au catalyst anywhere along this nanowire. FIG. 5B is a high resolution image of the same nanowire, and confirms the presence of multiple stacking faults and rough sidewalls. These observations are consistent with prior reports of the consequences of Au-migration, namely roughened sidewalls and tapering. The observed nanowire morphology may also be due to the low temperatures of these growths, which is also known to induce tapering. The corresponding diffraction pattern demonstrates that the crystalline structure is wurtzite, as expected. It has been shown that crystallographic phase is heavily impacted by the contact angle of the catalyst on the substrate and initial droplet radius, independent of the substrate. Namely, catalysts that are less than 25.5 nm in diameter induce the formation of the wurtzite crystal structure. This is consistent with nanowire width measurements at the apex near the catalyst (22±5 nm) in FIG. 4C. FIG. 5C shows a low resolution TEM image of a single Si doped nanowire. The nanowire is curved and no catalyst is visible along this nanowire. The catalyst may have migrated from the apex of the nanowire, contributing to the tapered morphology. This type of catalyst migration has also been observed in other nanowire growths. The sidewalls are uneven and there are regions of the nanowire with different widths. FIG. 5D is a high resolution image of the same nanowire. This image confirms the rough surfaces at the sidewalls of the nanowire. Also visible is a series of stacking faults. Regions such as these are common along the length of the nanowire, but there are fewer than the in undoped nanowire. The crystal orientation of this nanowire was also wurtzite as indicated by the diffraction pattern. FIG. 5C is a low resolution image of single Be doped nanowire clearly showing the Au catalyst at the nanowire tip. Furthermore, the sidewalls appear smooth and the diameter unchanging along the length of the nanowire. Earlier it was proposed that the smooth sidewalls are caused by the Be dopants having a surfactant effect on the sidewalls of the nanowire. It is also proposed that this surfactant effect may be preventing the migration of the Au catalyst from nanowire apex. A stable catalyst would also prevent nanowire tapering, as observed in FIG. 4C. FIG. 5D is a high resolution image of a single Be doped nanowire and its corresponding diffraction pattern. A few stacking faults are visible in this image, and the sidewalls are smooth. As with the undoped and Si doped nanowire, the diffraction pattern indicates that the crystal structure is wurtzite.

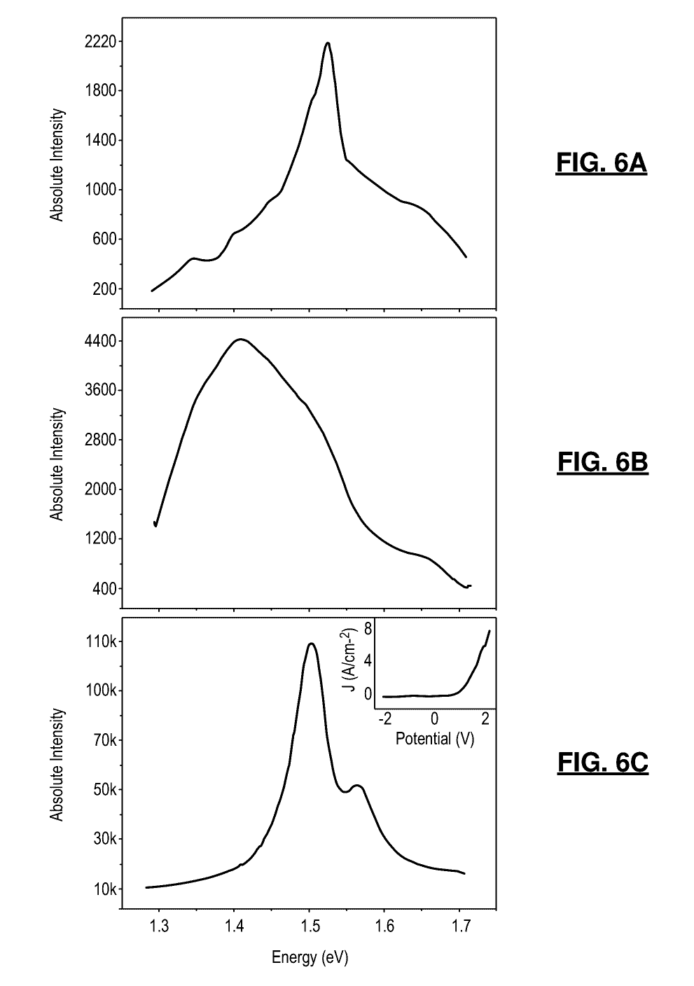

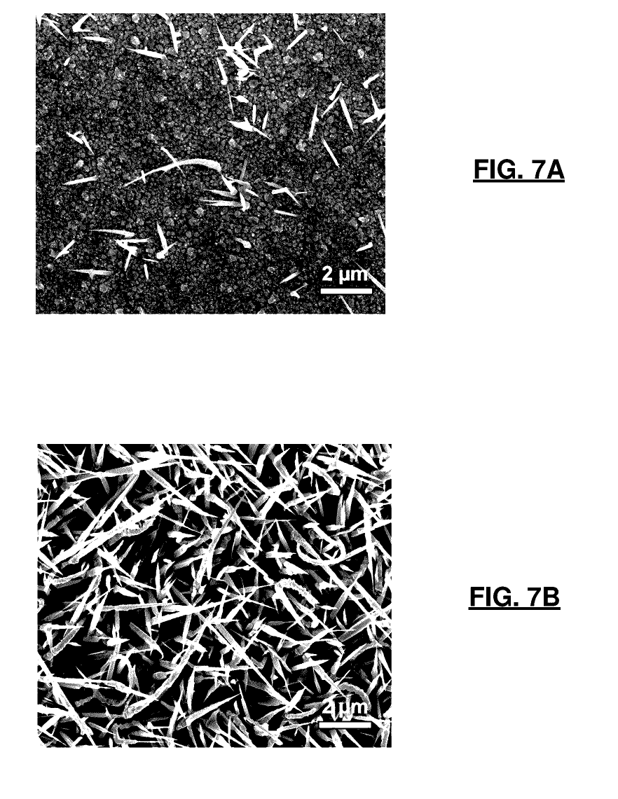

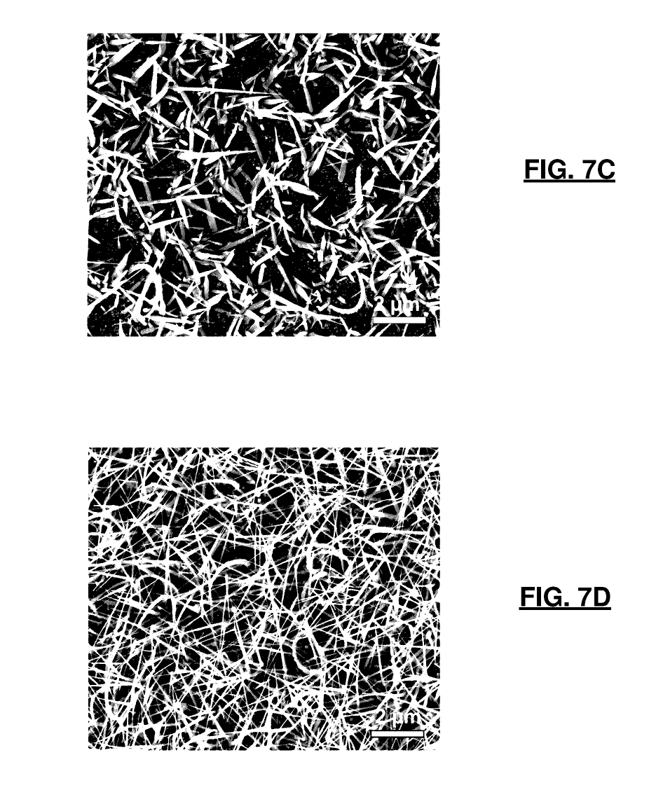

FIGS. 6A-6C shows photoluminescence measurements of nanowire forests still attached to the substrate carried out at 10 K with a 633 nm HeNe laser with an output power of 1 mW and a spot size of 5 um². Undoped nanowires have weak peak response at 1.52 eV (FWHM=45 meV) superimposed on less intense broad emission (FIG. 6a). The position of 1.52 eV is expected for GaAs but the cause of the broad background emission is not clear. The Si doped nanowires emit a weak broad peak at 1.41 eV (FWHM=210 meV) (FIG. 6B), which may be emission from a radiative defect caused by either Si or GaAs. Alternatively, emission in this range has previously been attributed to zinc-blende and wurtzite heterojunctions within GaAs nanowires. Be-doped nanowires have an optical response that is approximately 25 times stronger, with a major peak at 1.50 eV (FWHM −41 meV) and a secondary peak that is 20% as intense at 1.57 eV (FWHM=31 meV) (FIG. 6C). The 20 meV redshift of the primary peak likely corresponds to the Be-doping level and is consistent with other published PL measurements of Be-doped GaAs. The secondary peak at 1.57 eV could either be the result of quantum confinement or a Burstein-Moss effect. In order for this 70 meV blue shift to arise from quantum confinement, the nanowires would have to be on the order of 10 nm in diameter. While the diameter average of the nanowires in these samples is 40±10 nm, there is a small population of nanowires <15 nm in diameter near the substrate-nanowire interface. In order for the blue shift to arise from the Burstein-Moss effect, the doping concentration would have to be approximately 9.2×10¹⁹ cm⁻³. While it is difficult to quantify the dopant concentration in the nanowires themselves, the doping flux used in these experiments is high enough to make a Burstein-Moss related blue shift feasible.

The inset in FIG. 6C shows current density (J) versus voltage (V) measurements of Be-doped nanowires on ITO. Be doped nanowires were used because of their superior structural and optical characteristics. To perform electrical testing, the GaAs nanowires were backfilled with parylene, followed by the e-beam deposition of 10 nm of Ti and 100 nm of Au to act as a top contact. To ensure a strong connection between the nanowires and the top contact, the sample was annealed at 300° C. for 1 min and without this step there is an open circuit. A bottom contact was formed similarly on the backside of the Si wafer. The rectifying response in the IV curve at positive and negative voltages presented in FIG. 6C signifies that the nanowires and ITO substrate form a Schottky contact. This is unsurprising as ITO is known to form a Schottky contact with p-type GaAs.

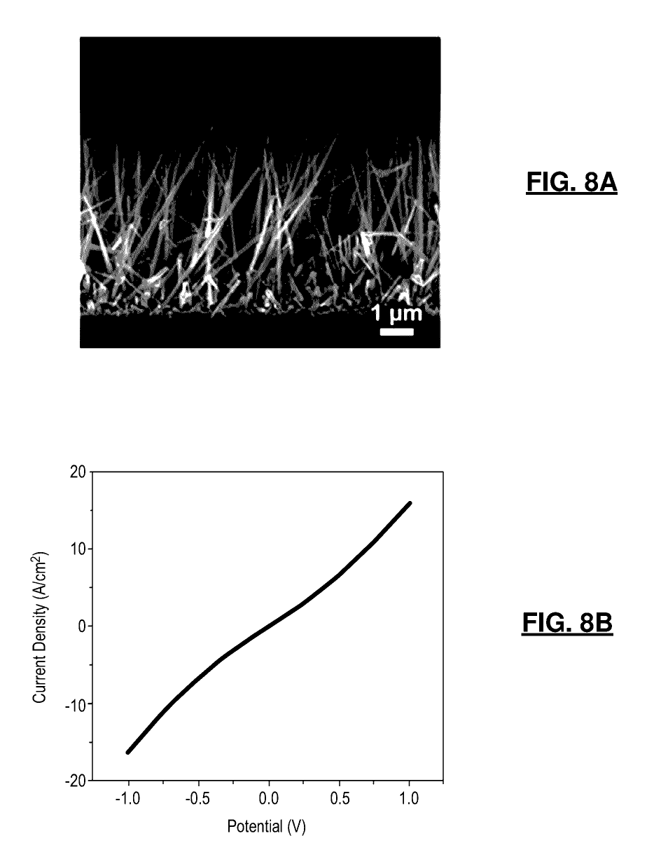

The growth of nanowires on polycrystalline metallic films that would form an Ohmic contact with GaAs were also explored. FIG. 7A shows top down SEM images of nanowires grown on Pt. FIG. 7A is a plan-view SEM image of nanowires grown under identical conditions as those in FIG. 1. While there is a small number of tapered nanowires of varying sizes, the majority of the substrate is covered by a rough contiguous film, likely the result of planar polycrystalline GaAs growth similar to the continuous film observed in FIG. 1C. The difference in the morphology between the two substrates is likely related to changes in the relative surface energies of the catalyst, conductive films, and GaAs. Nanowire formation via the VLS growth mode requires that the catalyst forms isolated droplets on the surface. At growth temperatures of 400° C., the deposited Au film is a solid, but because it forms a eutectic alloy, it melts upon the introduction of Ga. ITO has a lower surface energy (0.02-0.03 J m⁻²) compared to Au—Ga (1.15 J m⁻²), resulting in dewetting of the catalyst. Pt, on the other hand, has a much higher surface energy (2.3-2.8 J m⁻² thus exhibits a decreased tendency for droplet formation. The catalyst may be comprised of more complex alloys, namely AuₓPt_{y}Ga_{z} or AuₓIn_{y}Ga_{z} that could also impact the relative surface energy.

A higher Ga deposition rate is found to overcome this limitation and allow for nanowire formation. FIG. 7B is a plan-view SEM image of nanowires on Pt grown at a higher Ga deposition rate (1.3 MIs⁻¹). In contrast to the sample grown at the lower Ga deposition rate (0.8 MIs⁻¹) seen in FIG. 7A, the highly tapered and randomly angled nanowires in FIG. 7B completely cover the substrate surface. The faster deposition rate promotes random perturbations in the thickness of the catalyst layer, also called a Mullins-Sekerka instability, that can lead to the formation of distinct droplets that in turn catalyze nanowire growth. The effect of dopants on the nanowire shape is similar for these samples as for those grown on ITO. FIG. 7C is a plan-view SEM image of GaAs nanowires doped with Si deposited at a high rate on Pt. Here, the nanowire density is somewhat lower than for the undoped samples, suggesting that the addition of Si inhibits nanowire growth. The addition of Be results in very thin, randomly angled nanowires forming a dense forest (FIG. 7D). Occasional curved nanowires are observed in all of the samples grown on Pt.

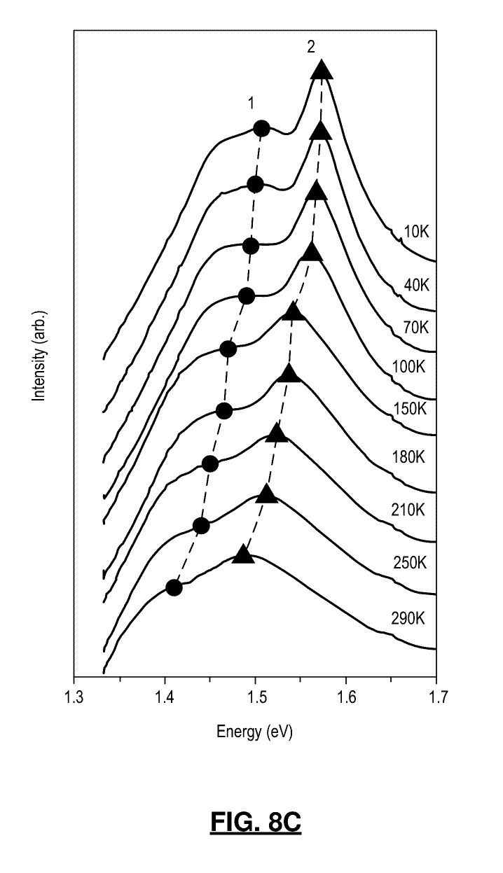

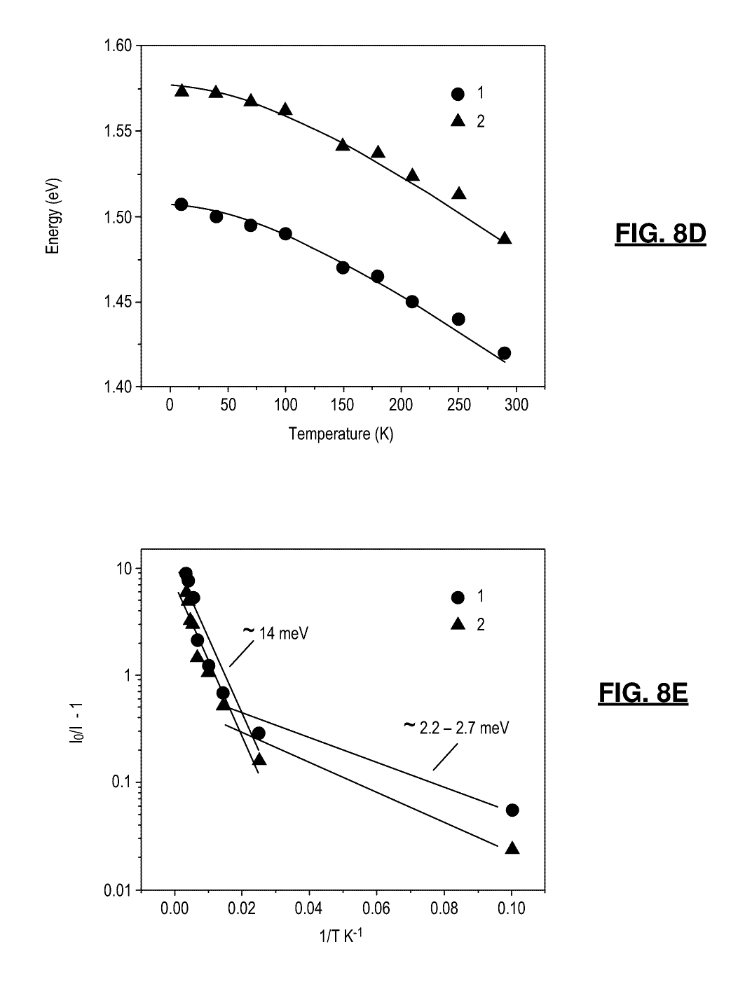

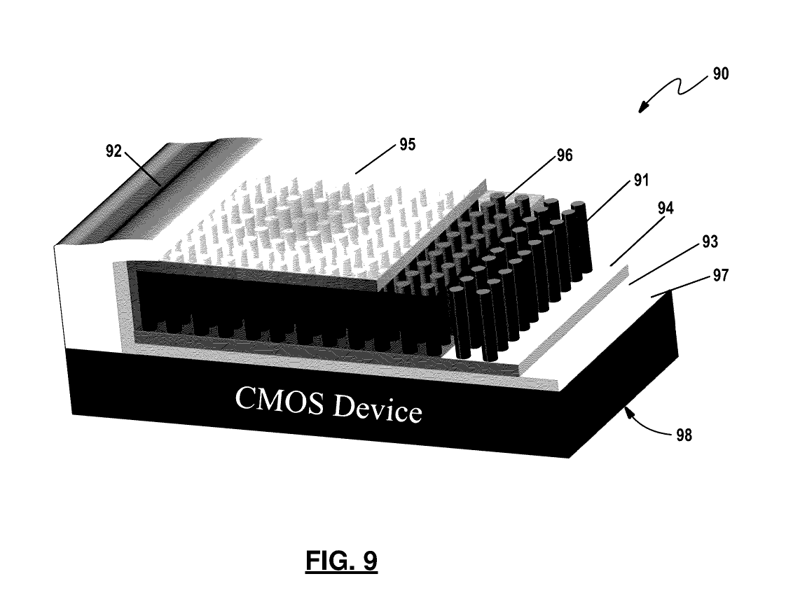

Nanowire growth was explored on Ti as well. FIGS. 8A-8E show the characterization of Be-doped nanowires grown on Ti. Nanowire growth on Ti behaved similarly to Pt, as evident from the cross-sectional SEM image (FIG. 8A). FIG. 8B depicts the current density characteristics of Be-nanowires on Ti films. The samples were prepared for IV measurements in an identical manner to the samples with ITO films. The IV curve for the nanowires grown on Ti is linear at positive and negative voltages, meaning the Be—GaAs nanowires form an Ohmic connection with the Ti film. This is promising for the development of nanowire based optoelectric devices on polycrystalline substrates.

Given their Ohmic contact with the underlying substrate, Be doped nanowires grown on Ti were measured optically using temperature dependent photoluminescence to better assess their quality (FIG. 8C). The undoped and Si doped nanowires did not exhibit a strong enough photoluminescence response for room temperature measurements. Primary peaks at 1.50 (labeled as peak 1 in FIG. 7(c)) and 1.57 eV (peak 2) at 10 K shift to 1.41 and 1.50 eV at room temperature. The intensity decreases and the peaks become less defined with increasing temperature. The 1.50 and 1.40 peak at 10 K and room temperature respectively correspond to the p-type GaAs. Similar to FIG. 6C, it is believed that the higher energy peak is the result of either a Burstein-Moss effect or quantum confinement. In the case of nanowires grown on Ti, this higher energy peak is significantly more pronounced. The position of this peak at room temperature is identical to that of another study of GaAs nanowires in which the optical emission of single nanowires are measured for quantum confinement. The fact that there is a strong optical response at room temperature suggests that these nanowires are of sufficient quality to be used in optoelectronic devices. Compared to single nanowire measurements, our photoluminescence peaks are slightly broadened as they represent an average of the nanowire forest.

FIG. 8D shows the temperature dependence of the emission energy of peaks 1 and 2. The trendlines were calculated using the Varshni equation, for bulk GaAs, but modified with different energies at T=0K (E_{G0}). The energy positions of the both peaks decrease with increasing temperature and closely follow the calculated trendline. This close correlation suggests the nanowire features represented by peaks 1 and 2 have a similar temperature dependence to bulk GaAs. This is expected and provides evidence for similarities between the nanowires and single-crystalline bulk GaAs.

FIG. 8E shows the plot of I₀/I−1 versus 1/T, where I₀ is the integrated photoluminescence intensity extrapolated at T=OK and I is the integrated photoluminescence intensity at temperature T, in order to determine the thermal activation energy for exciton formation (E_{A}). At temperatures above 50 K we see quenching of the intensity, corresponding to an E_{A} of approximately 14 meV. For comparison, nanowires grown near 600° C. at GaAs and Si crystalline substrates have been reported with high temperature E_{A} of 17 meV and 77 meV respectively. This suggests that the Be doped nanowires presented in this study are comparable to those grown at high temperatures on crystalline substrates.

FIG. 9 illustrates an example optoelectronic device 90 fabricated in accordance with this disclosure. The optoelectronic device 90 includes an active region 91 comprised of nanowires and sandwiched between a top contact layer 92 and a bottom contact layer 93. In this example, a portion of the top contact layer 95 is comprised of a transparent conductive material, such as ITO. A polycrystalline film 94 is interposed between the active region 91 and the bottom contact layer 93. It is understood that the nanowires of the active region 91 are grown in the manner described above.

Additionally, the bottom contact layer 93 may be formed over top of and in directed contact with a CMOS device 98. In some embodiments, an insulating layer 97 may be interposed between the bottom contact layer 93 and the top planar surface of the CMOS device 98. It is also envisioned that the optoelectronic device may be arranged lateral to the CMOS device 98. In any case, the optoelectronic device and the CMOS device are fabricated together and prior to the step of integrated circuit packaging.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. A method for fabricating an optoelectronic device, comprising:
forming a bottom contact layer on a substrate;
growing a plurality of nanowires on the bottom contact layer at a temperature less than or equal to 450 degrees Celsius, where the nanowires are comprised of a group III-V semiconductor material;
depositing an insulating material onto the nanowires to form an active layer; and
forming a top layer on top of the active layer, where the top layer and the bottom contact layer are comprised of a conductive material.

2. The method of claim 1 wherein growing the plurality of nanowires further comprises depositing gallium arsenide doped with beryllium onto the bottom contact layer prior to depositing gallium arsenide doped with silicon onto the deposited gallium arsenide doped with beryllium.

3. The method of claim 1 wherein the nanowires are comprised of gallium arsenide doped with beryllium.

4. The method of claim 1 wherein growing the plurality of nanowires further comprises depositing gallium arsenide onto the bottom contact layer using molecular beam epitaxy.

5. The method of claim 1 further comprises growing the plurality of nanowires on the bottom contact layer at 400 degrees Celsius.

6. The method of claim 1 further comprises depositing a catalyst onto the bottom contact layer prior to the step of growing the plurality of nanowires.

7. The method of claim 6 wherein the catalyst is selected from a group consisting of gold, nickel, silver and tin.

8. The method of claim 1 wherein the conductive material for the bottom contact layer is selected from a group consisting of indium tin oxide, platinum, and titanium gold.

9. The method of claim 1 further comprises forming a bottom contact layer in direct contact with a complementary metal-oxide-semiconductor (CMOS) circuit prior to integrated circuit packaging.

10. The method of claim 1 wherein forming a top layer on top of the active layer further comprises depositing a metal onto the active layer and annealing the optoelectronic device after the step of depositing the metal.

11. A method for forming a bottom contact layer on a substrate, comprising:
forming a bottom conductive layer;
growing a plurality of nanowires at or below 450 degrees Celsius on the bottom conductive layer by depositing a group III-V semiconductor material doped with a first dopant followed by depositing the same semiconductor material doped with a second dopant different than the first dopant;
depositing a catalyst onto the bottom contact layer prior to the step of growing nanowires
depositing an insulating material onto the nanowires to form an active layer; and
forming a top conductive layer on top of the active layer.

12. The method of claim 11 wherein growing the plurality of nanowires further comprises depositing the semiconductor material from group III-V using molecular beam epitaxy.

13. The method of claim 11 wherein the catalyst is selected from a group consisting of gold, nickel, silver and tin.

14. The method of claim 11 wherein the conductive material for the bottom contact layer is selected from a group consisting of indium tin oxide, platinum, and titanium gold.

15. The method of claim 11 further comprises forming a bottom contact layer in direct contact with a complementary metal-oxide-semiconductor (CMOS) circuit prior to integrated circuit packaging.

16. An integrated circuit package, comprising:
a complementary metal-oxide-semiconductor (CMOS) device residing in the integrated circuit package; and
an optoelectric device residing in the integrated circuit package proximate to the CMOS device, wherein the optoelectric device includes an active region comprised of nanowires and the active region is sandwiched between a top contact layer and a bottom contact layer, wherein the nanowires are grown from a group III-V semiconductor materials at or below 450 degrees Celsius.

17. The integrated circuit package of claim 16 further comprises a polycrystalline film interposed between the active region and the bottom contact layer.

18. The integrated circuit package of claim 16 wherein the top contact layer and the bottom contact layer are comprised of conductive materials.

19. The integrated circuit package of claim 16 wherein the optoelectric device is disposed on top of the CMOS device with an insulating layer interposed between the optoelectric device and the CMOS device.
